(19) United States
(12) Patent Application Publication
(10) Pub. No.: US 2015/0287871 A1
(43) Pub. Date: Oct. 8, 2015

(54) SOLUTION-PROCESSED ULTRAVIOLET LIGHT DETECTOR BASED ON P-N JUNCTIONS OF METAL OXIDES

(71) Applicant: UNIVERSITY OF FLORIDA RESEARCH FOUNDATION, INC., Gainesville, FL (US)

(72) Inventors: Jesse Robert Manders, Gainesville, FL (US); Do Young Kim, Gainesville, FL (US); Jiho Ryu, Yongin (KR); Jae Woong Lee, Gainesville, FL (US); Franky So, Gainesville, FL (US)

(21) Appl. No.: 14/440,510

(22) PCT Filed: Nov. 5, 2013
(86) PCT No.: PCT/US2013/068435

§ 371 Date: May 4, 2015

Related U.S. Application Data
(60) Provisional application No. 61/722,403, filed on Nov. 5, 2012.

(51) Int. Cl. H01L 31/101; H01L 31/18; H01L 31/0352; H01L 31/109; H01L 31/032; H01L 31/0296

(52) U.S. Cl. CPC H01L 31/1016; H01L 31/032; H01L 31/0296; H01L 31/035218; H01L 31/109; H01L 31/1828; H01L 31/18

(57) ABSTRACT

An ultraviolet light detector has a pn-junction of wide-gap semiconductors layers, where a p-type semiconductor layer with a polycrystalline metal oxide contacts an n-type semiconductor layer of metal oxide nanoparticles, or the converse. The ultraviolet detector is prepared using solvent based deposition methods and where temperatures can be maintained below 300° C.

### CROSS-REFERENCE TO RELATED APPLICATION

The present application claims the benefit of U.S. Provisional Application Ser. No. 61/722,403, filed Nov. 5, 2012, which is hereby incorporated by reference herein in its entirety, including any figures, tables, or drawings.

### BACKGROUND OF INVENTION

Ultraviolet (UV) light detectors are important devices with applications in a wide variety of fields of study and industries. Among the most prominent applications are solar-blind detectors, sensing for biologically damaging or biologically stimulating UV irradiation, detection of the presence or absence of the atmospheric UV-absorber ozone, and detection of UV light used for photolithography in semiconductor wafer manufacturing. Conventional photodetectors for these applications are typically made in vacuum processing conditions that are incompatible with high throughput rather than inexpensive fabrication techniques, such as, solution processing with flexible substrates. UV-detectors have been primarily composed of a pn-junction of wide-gap semiconductors. UV-detectors have been developed where the wide-gap semiconductors are GaN, ZnSe, ZnS and diamond based systems.

Transparent oxide semiconductors (TOSs) are preferable for the fabrication of UV-detectors, because TOSs are optically transparent in visible and near UV-light region, environmentally friendly, thermally stable, and chemically stable. Ohta el al., Thin Solid Films 2003, 445, 317-21, teach a UV-detector based on a pn-heterojunction of p-type (Li⁺ doped) NiO and n-type ZnO. The ZnO epitaxial layer was grown on a single-crystalline NiO, because of the similarity of the oxygen atomic configurations (six-fold symmetry) of (0 0 0 2) ZnO and (1 1 1) NiO. The pn-heterojunction of n-ZnO and p-NiO films had high crystalline qualities and an abrupt hetero-interface due to the pulsed-laser-deposition (PLD) method employed in conjunction with a solid phase-epitaxy (SPE) technique. Processing included steps of annealing at 1300° C. to convert the polycrystalline NiO to a single crystalline NiO while capped with an yttrium stabilized zirconia (YSZ) plate to suppress Li₂O vaporization during annealing, followed by growth of the ZnO on the NiO:Li film at 700° C. The diode exhibited clear rectifying I-V characteristics with a forward threshold voltage of ˜1 V, which is significantly lower than the direct band gap energies of ZnO and NiO. The detector displayed an efficient UV-response up to ˜0.3 AW⁻¹ at 360 nm (−6 V biased), which is a value comparable to those of commercial GaN UV-detectors (˜0.1 AW⁻¹). Nevertheless, the processing has proved prohibitive for commercial products. More recently, Wang et al. Journal of Applied Physics 2007, 101, 114508 disclosed p-NiO/i-ZnO/n-ITO and n-ITO/i-ZnO/p-NiO diodes, by reversing the deposition order. The p-NiO and i-ZnO films were prepared by reactive oxygen-ion-beam-assisted e-beam evaporation from high purity zinc and nickel. Thin film properties were controlled by adjusting the energy and flux of oxygen ion beam.

Other ZnO based UV-detectors have been formed with other wide band gap p-type semiconductors, such as p-SiC and GaN, which are also transparent in the visible region. Alivov et al. Applied Physics Letters 2005 86, 241108, discloses an n-ZnO/p-SiC heterojunction photodiode made by molecular beam epitaxy (MBE) to form a detector with a photoresponse of as high as 0.045 AW⁻¹. Zhu et al. J. Phys. Chem. C 2008, 112, 20546-8, discloses the deposited undoped n-type ZnO film on a p-type GaN substrate to form a p-n heterojunction photodiode, again using MBE to form a photodetector with an enhanced UV photoresponse in a spectrum range 17 nm in width, suggesting that the high selectivity of the GaN layer acts as a “filter” for the photodetector.

Hence it remains desirable to form a visible transparent UV-detector comprising a pn-heterojunction photodiode using a method of preparation that is low cost and amenable to pn-junctions made from p-type metal oxides that selectively transport holes, such as nickel oxide (NiO), and n-type metal oxides that selectively transport electrons, such as zinc oxide (ZnO) or titanium dioxide (TiO₂). These materials are very attractive for components of a UV detector because these materials strongly absorb light only in the ultraviolet part of the electromagnetic spectrum allowing the construction of visibly transparent devices.

### BRIEF SUMMARY

Embodiments of the invention are directed to an ultraviolet light (UV) detector where the detecting structure is a pn-junction of wide-gap semiconductors layers where the junction occurs at the contact between a p-type semiconductor polycrystalline metal oxide layer and an n-type metal oxide nanoparticle semiconductor layer. In an embodiment of the invention, the polycrystalline metal oxide can be NiO and the metal oxide nanoparticles can be ZnO. Alternatively, the n-type polycrystalline metal oxide layer can comprise any of: Mn:SnO₂; CuAlO₂; CuGaO₂; CuInO₂; or SrCu₂O₂, and the metal oxide nanoparticles can comprise any of: TiO₂, MoO₃, or V₂O₅. The nanoparticles can be 2 to 100 nm in cross-section. The detecting structure of the UV detector can be formed by a solution process.

An embodiment of the invention is directed to a method to prepare the UV detector, where a substrate covered with an electrode layer, a cathode, has a p-type polycrystalline metal oxide layer deposited thereon, to which an n-type nanoparticulate metal oxide layer is deposited, and, ultimately, a counter-electrode layer, an anode, is formed thereon. The p-type polycrystalline metal oxide layer is deposited by placing a solution of a metal oxide precursor on the electrode layer and removing the solvent to form a film of the p-type polycrystalline metal oxide layer upon heating up to about 800° C., but can be a temperature less than 300° C. The n-type nanoparticulate metal oxide layer is deposited by placing a suspension of metal oxide nanoparticles on the p-type polycrystalline metal oxide layer and removing the suspending fluid.

In other embodiments of the invention, the polycrystalline metal oxide layer is an n-type semiconductor and the nanoparticulate metal oxide layer is a p-type semiconductor. In an embodiment of the invention, the polycrystalline metal oxide can be ZnO and the metal oxide nanoparticles can be NiO.

In other embodiments of the invention, the method of forming the pn-j unction of the UV detector is to deposit a solution of a metal oxide precursor, for example, a ZnO precursor, on the electrode layer and to remove the solvent to form a film of the n-type polycrystalline metal oxide layer upon heating up to about 800° C. The p-type nanoparticulate metal oxide layer is deposited by placing a suspension of metal oxide nanoparticles, for example, NiO nanoparticles, on the n-type polycrystalline metal oxide layer.

### BRIEF DESCRIPTION OF DRAWINGS

FIG. 1 shows a schematic drawing of ultraviolet (UV) detectors according to embodiments of the invention, where a) shows a “standard structure” with the anode on a supporting substrate and b) shows an “inverted structure” with a cathode on a supporting substrate.

FIG. 2 shows transmission spectra of a) NiO and b) ZnO in the form of a polycrystalline continuous film and nanoparticles, respectively, which are the layer forms employed in UV detectors, according to an embodiment of the invention.

FIG. 3 shows a plot of the current-voltage characteristics of a UV detector, according to an embodiment of the invention, with a standard structure of a polycrystalline NiO layer and a ZnO nanoparticulate layer, a quartz substrate, an anode, and a cathode in the dark and under UV-illumination at 350 nm.

FIG. 4 shows a plot of the UV spectral detectivity of the UV detector, according to an embodiment of the invention, characterized in FIG. 3.

FIG. 5 shows a plot of the UV spectral external quantum efficiency (EQE) of an UV detector, according to an embodiment of the invention, characterized in FIG. 3.

FIG. 6 shows a grazing incidence X-ray diffraction (GIXRD) pattern for a NiO film fabricated at 275° C., in a manner, according to an embodiment of the invention to prepare a UV detector, and the signals for bulk crystalline NiO.

FIG. 7 shows a powder X-ray diffraction plot for dried quasi-spherical ZnO nanoparticles of 6 nm in diameter for use in a UV detector, according to an embodiment of the invention.

FIG. 8 shows a transmission electron micrograph of a single ZnO nanoparticle for use in a UV detector, according to an embodiment of the invention.

### DETAILED DISCLOSURE

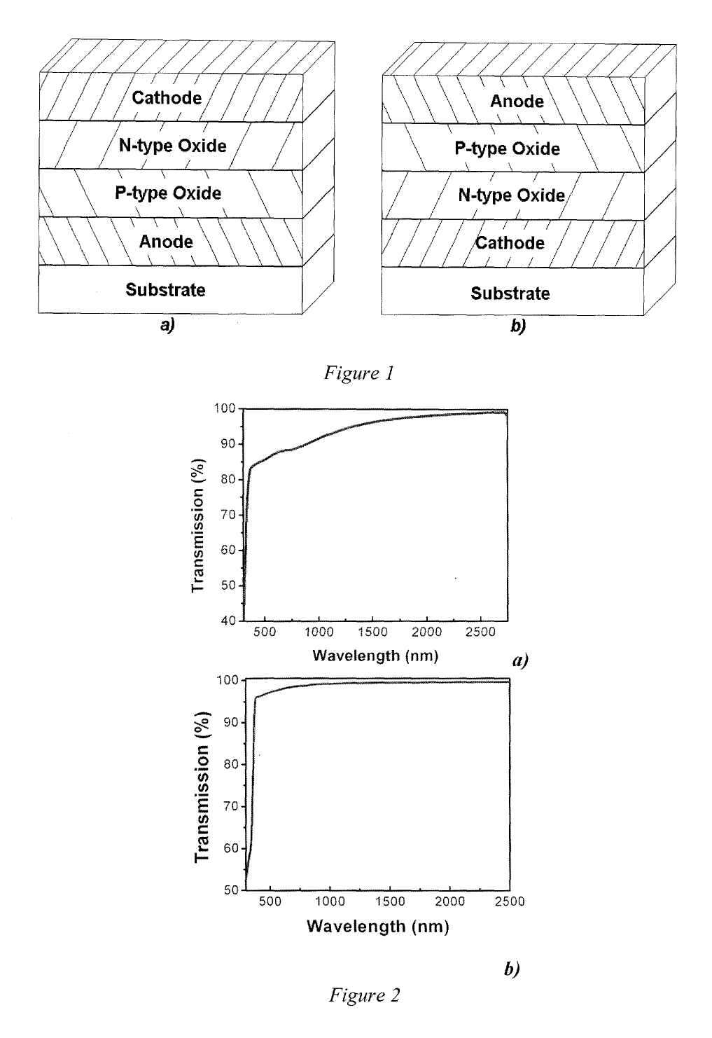

Embodiments of the invention are directed to a UV light detector comprising a pn-diode consisting of a p-type metal oxide, such as, NiO, Mn:SnO₂, CuAlO₂, CuGaO₂, CuInO₂, or SrCu₂O₂, and an n-type metal oxide, such as, ZnO, TiO₂, MoO₃, or V₂O₅, and to a method of forming the pn-junction of the wide-gap semiconductors layers that is fully solution-processed. In one embodiment of the invention, the UV light detector is constructed on any suitable substrate upon which an anode is deposited. Subsequently, nickel oxide or other p-type metal oxide is deposited as a layer on the anode, followed by deposition of zinc oxide, titanium dioxide, or other n-type metal oxide as a layer. The active portion of the UV detector is completed by deposition of a cathode on the n-type metal oxide. This “standard structure” is composed of layers to give a device structure of: substrate/anode/p-type oxide/n-type oxide/cathode. Alternatively, according to another embodiment of the invention, a UV detector is fabricated with an “inverted structure” where the layers are: substrate/cathode/n-type oxide/p-type oxide/anode. Both structures, as shown in FIG. 1, are vertically oriented, in that charge transport in the device proceeds vertically between the electrodes, having a diode configuration rather than the horizontal manner common to a traditional photoconductor.

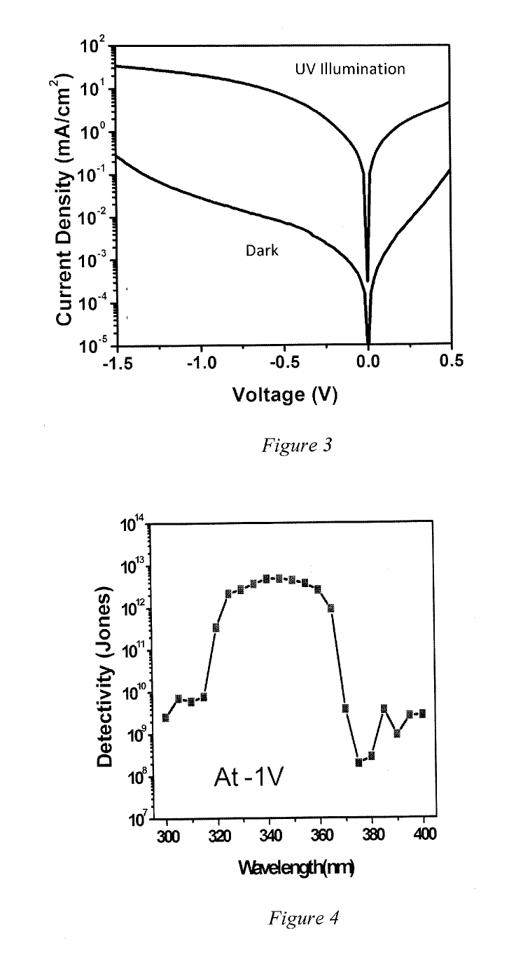

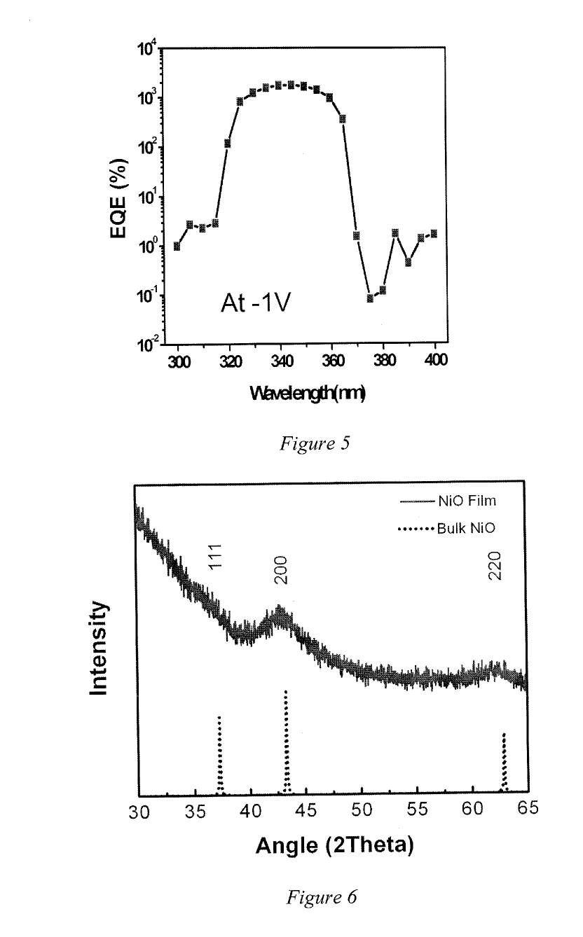

In this manner, the UV detector can be integrated into large area devices and fabricated using a high throughput method. In an embodiment of the invention, deposition occurs by a solution process with NiO and ZnO as the p-type and n-type materials, respectively. Optical absorption measurements confirm the materials absorb strongly in the UV portion of the electromagnetic spectrum, as shown in FIG. 2 for a) NiO and b) ZnO. ZnO UV absorption occurs at wavelengths shorter than 365 nm, while NiO UV absorption occurs at wavelengths shorter than 330 nm. Dark and UV-illuminated current-voltage characteristics of these UV detectors are shown in FIG. 3. The detectivity and external quantum efficiency (EQE) of these UV detectors are shown in FIGS. 4 and 5, respectively. EQE is defined as the ratio of the number charge carriers, either electrons or holes, extracted from the detector to the number of photons incident on the detector. The EQE exceeds 100% with a negative applied bias (−1 V) with these NiO/ZnO based devices. In this bias region, the current “gain” is greater than unity. This is advantageous for devices and applications, which benefit from a high output signal strength at low signal input. These devices are well-suited for emerging and established applications due to the ease of fabrication and the high performance of these detectors.

According to embodiments of the invention, the devices are fabricated by sequential deposition of the metal oxide layers. A substrate with the electrode deposited is used as the surface for deposition of the metal oxide layers. When the electrode is an anode, for example, ITO, IZO, AZO, FTO, Au, Ag, Mg:Ag, or Al, a NiO precursor solution is deposited and subsequently heated to a desired temperature for formation of a NiO layer, where the nature of the precursor and the temperature employed, for example, 100 to 800° C., determine the grain sizes and defect density of the NiO film. After the NiO is deposited and cooled to ambient or other desired temperature, a second metal oxide, for example, ZnO nanoparticles, is deposited directly onto the NiO film. For example, ZnO nanoparticles of 1 to 100 nm in the form of dots, wires, or rods can be used After deposition of the ZnO nanoparticles, a counter-electrode, a cathode, is deposited by thermal evaporation or any appropriate alternate film deposition method. Appropriate cathodes include, but are not limited to, ITO, IZO, AZO, FTO, Au, Ag, Mg:Ag, or Al. The device can have an inverted structure, as indicated in FIG. 1b, by inverting the nature and order of deposition of the electrodes and the order of deposition of the metal oxide layers. Methods by which the metal oxide layers can be deposited include, but are not limited to, spin-coating, inkjet printing, or any method compatible with appropriate solvents for construction of large or small area devices.

In embodiments of the invention, the layers are deposited from solution. In embodiments of the invention, the NiO precursor solution is one where the coordination complexed Ni precursor solute is dissolved in an organic solvent, such as, but not limited to, ethanol, methanol, 2-methoxyethanol, or 2-ethoxyethanol. The source of the nickel cation in solution is from any common alcohol soluble nickel salt, such as, but not limited to, nickel acetate, nickel formate, or nickel chloride. The coordinating ligand can be, but is not limited to, ethylenediamine or monoethanolamine.

In an embodiment of the invention the ZnO layer is a nanoparticulate layer. ZnO nanoparticles can be synthesized through a solution-precipitation method. Deposition of the ZnO nanoparticles can be from a dispersion of the nanoparticles in a solvent, for example, ethanol.

In an embodiment of the invention, the UV detector has an inverted structure, where an n-type semiconductor layer comprising a polycrystalline metal oxide contacts a p-type semiconductor layer comprising a multiplicity of metal oxide nanoparticles. The device fabrication can be carried out in an analogous fashion to the device comprising a p-type polycrystalline metal oxide layer and an n-type metal oxide nanoparticle layer. For example, a layer of ZnO can be deposited on a cathode layer from a ZnO precursor solution, for example, a zinc acetate solution in 2-methoxyethanol, followed by baking to form an n-type polycrystalline layer, to which a dispersion of NiO nanoparticles can be deposited on the ZnO polycrystalline layer to yield a p-type nanoparticulate layer.

### METHODS AND MATERIALS

To fabricate a NiO film, the coordination complex precursor solution was prepared from a precursor, in which nickel acetate tetrahydrate was dissolved in ethanol. Ethanolamine was added to the precursor as a stabilizer in equal molar concentration to nickel acetate tetrahydrate. The precursor solution was deposited on a substrate and the resulting solute film was baked on a hotplate. The resulting film is polycrystalline, with a grain size that depends on the baking temperature. For example, baking at a temperature of 275° C. results in approximately 1 nm grains with a typical rock salt (NaCl) crystal structure; this is revealed by a grazing incidence X-ray diffraction (GIXRD) pattern, as shown in FIG. 6.

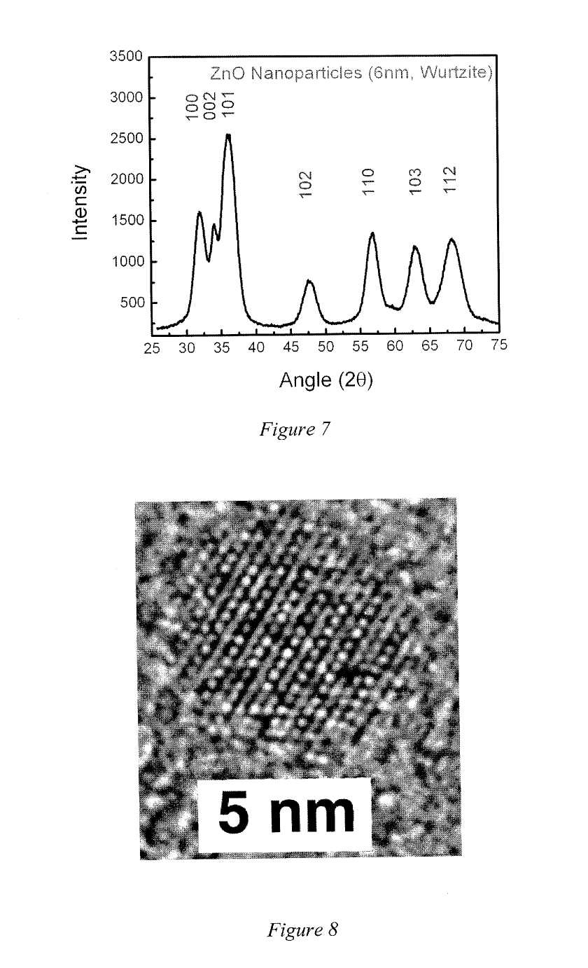

Equimolar solutions of zinc acetate dihydrate and tetramethylammonium hydroxide were mixed together while stirring at ambient temperatures and pressures. After growth for a short duration, colloidal ZnO nanoparticles were precipitated by addition of a non-solvent, such as ethyl acetate or heptanes, and washed to remove excess reactants. The resulting ZnO nanoparticles are approximately 6 nm in diameter and quasi-spherical single crystals. X-ray diffraction and transmission electron microscopy confirm the ZnO nanoparticles' size and shape, as shown in FIGS. 7 and 8. The ZnO nanoparticles were dispersed in ethanol for deposition on the NiO layer.

All publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

We claim:

1. An ultraviolet light detector, comprising a pn-j unction of wide-gap semiconductors layers, wherein a p-type semiconductor layer comprising a polycrystalline metal oxide contacts an n-type semiconductor layer comprising a multiplicity of metal oxide nanoparticles.

2. The ultraviolet light detector according to claim 1, wherein the polycrystalline metal oxide comprises NiO, Mn:SnO₂, CuAlO₂, CuGaO₂, CuInO₂, or SrCu₂O₂.

3. The ultraviolet light detector according to claim 1, wherein the metal oxide nanoparticles comprise ZnO, TiO₂, MoO₃, or V₂O₅.

4. The ultraviolet light detector according to claim 1, wherein the metal oxide nanoparticles are 2 to 100 nm in cross-section.

5. A method to prepare an ultraviolet light detector according to claim 1, comprising:
providing a substrate;
depositing an electrode layer on the substrate;
depositing a p-type polycrystalline metal oxide layer;
depositing an n-type nanoparticulate metal oxide layer; and
depositing a counter-electrode layer.

6. The method of claim 5, wherein the electrode layer is an anode.

7. The method of claim 5, wherein depositing a p-type polycrystalline metal oxide layer comprises: placing a solution of a metal oxide precursor on the electrode layer or on the n-type nanoparticulate metal oxide layer; removing the solvent of the solution to form a film of a solute, and heating the film of the solute to form the p-type polycrystalline metal oxide layer.

8. The method of claim 7, wherein heating is to a temperature less than 300° C.

9. The method of claim 5, wherein depositing an n-type nanoparticulate metal oxide layer comprises: providing a multiplicity of metal oxide nanoparticles; suspending the metal oxide nanoparticles in a fluid to form a suspension; placing the suspension on the electrode or on the p-type polycrystalline metal oxide layer; and removing the fluid to form the n-type nanoparticulate metal oxide layer.

10. An ultraviolet light detector, comprising a pn-junction of wide-gap semiconductors layers, wherein an n-type semiconductor layer comprising a polycrystalline metal oxide contacts a p-type semiconductor layer comprising a multiplicity of metal oxide nanoparticles.

11. The ultraviolet light detector according to claim 10, wherein the polycrystalline metal oxide comprises ZnO, TiO₂, MoO₃, or V₂O₅.

12. The ultraviolet light detector according to claim 10, wherein the metal oxide nanoparticles comprise NiO, Mn:SnO₂, CuAlO₂, CuGaO₂, CuInO₂, or SrCu₂O₂.

13. The ultraviolet light detector according to claim 10, wherein the metal oxide nanoparticles are 2 to 100 nm in cross-section.

14. A method to prepare an ultraviolet light detector according to claim 10, comprising:
providing a substrate;
depositing an electrode layer on the substrate;
depositing an n-type polycrystalline metal oxide layer;
depositing a p-type nanoparticulate metal oxide layer; and
depositing a counter-electrode layer.

15. The method of claim 14, wherein the electrode layer is a cathode.

16. The method of claim 14, wherein depositing a p-type polycrystalline metal oxide layer comprises: placing a solution of a metal oxide precursor on the electrode layer or on the n-type nanoparticulate metal oxide layer; removing the solvent of the solution to form a film of a solute, and heating the film of the solute to form the p-type polycrystalline metal oxide layer.

17. The method of claim 14, wherein depositing an n-type nanoparticulate metal oxide layer comprises: providing a multiplicity of metal oxide nanoparticles; suspending the metal oxide nanoparticles in a fluid to form a suspension; placing the suspension on the electrode or on the p-type polycrystalline metal oxide layer; and removing the fluid to form the n-type nanoparticulate metal oxide layer.
